(19) United States
(12) Patent Application Publication
(10) Pub. No.: US 2026/0020385 A1
(43) Pub. Date: Jan. 15, 2026

(54) LIGHT EMITTING DIODE AND LIGHT EMITTING MODULE HAVING THE SAME

(71) Applicant: SEOUL VIOSYS CO., LTD., Ansan-si (KR)

(72) Inventor: Hyoshik CHOI, Ansan-si (KR)

(21) Appl. No.: 19/268,639

(22) Filed: Jul. 14, 2025

Related U.S. Application Data
(60) Provisional application No. 63/671,533, filed on Jul. 15, 2024.

(51) Int. Cl. H10H 20/821; H10H 20/81; H10H 29/24

(52) U.S. Cl. CPC H10H 20/821; H10H 20/8215; H10H 29/24

(57) ABSTRACT

A light emitting diode and a light emitting module having the same are disclosed. A light emitting diode according to an embodiment of the present disclosure includes a first conductivity type semiconductor region including a first dopant, a light emitting region including a barrier layer and a well layer, a second conductivity type semiconductor region including a second dopant, and an approach region disposed between the first conductivity type semiconductor region and the second conductivity type semiconductor region, in which a profile of the second dopant extends from the second conductivity type semiconductor region to the approach region, and at least a portion of the approach region is overlapped with the light emitting region.

### CROSS-REFERENCE TO RELATED APPLICATIONS

This application claims priority to and the benefit of U.S. Provisional Application No. 63/671,533, filed on Jul. 15, 2024. The aforementioned application of which is incorporated herein by reference in its entirety.

### TECHNICAL FIELD

The present disclosure relates to a light emitting diode and a light emitting module.

### BACKGROUND ART

A light emitting diode is used as a light source in a display apparatus, a traffic light, lighting, and an optical communication apparatus. In particular, a nitride-based light emitting diode can emit light of various colors from ultraviolet to red by controlling a composition ratio of Al, Ga, and In. The nitride-based light emitting diode injects electrons and holes into a light emitting region having a quantum well structure and generates light through their combination.

To improve a radiation efficiency of the light emitting diode, the injection efficiency of electrons and holes has to be improved, and in particular, the injection efficiency of holes needs to be improved.

### SUMMARY

### Technical Problem

Embodiments of the present disclosure provide a light emitting diode that is configured to improve the injection efficiency of holes in a light emitting region.

### Technical Solution

A light emitting diode according to an embodiment of the present disclosure includes: a first conductivity type semiconductor region including a first dopant; a light emitting region including a barrier layer and a well layer; a second conductivity type semiconductor region including a second dopant; and an approach region disposed between the first conductivity type semiconductor region and the second conductivity type semiconductor region, in which a profile of the second dopant extends from the second conductivity type semiconductor region to the approach region, and at least a portion of the approach region is overlapped with the light emitting region.

In an embodiment, the approach region may include a first region having a relatively gentle slope and a second region having a slope steeper than that of the first region.

In an embodiment, an absolute value of a peak-to-peak slope in the first region may be smaller than that of a peak-to-peak slope in the second region

In addition, an absolute value of a valley-to-valley slope in the first region may be smaller than that of a valley-to-valley slope in the second region.

The second dopant profile may have a peak near a surface of the second conductivity type semiconductor region and a peak near the light emitting region within the second conductivity type semiconductor region, and moreover, it may have a region in which a concentration of the second dopant increases as a depth increases between the peaks.

The approach region includes a first region having a relatively gentle slope and a second region having a slope steeper than that of the first region, and an absolute value of a slope of the region in which the concentration of second dopant increases between the peaks may be greater than an absolute value of the slope of the first region.

A slope of the second dopant profile in the first region may be different from that of a first dopant profile.

A slope of the second dopant profile in the second region may be different from that of the first dopant profile.

The first conductivity type semiconductor region includes a high concentration doping region doped with a relatively high concentration of the first dopant and a low concentration doping region doped with a relatively low concentration of the first dopant, in which a Si doping concentration of the high concentration doping region may be higher than that of the second dopant in the approach region.

The approach region includes a first region having a relatively gentle slope and a second region having a slope steeper than that of the first region, in which a maximum concentration of the first dopant profile in the low concentration doping region may be higher than second dopant concentrations in the first region and the second region.

In an embodiment, the light emitting diode may further include a superlattice region disposed between the first conductivity type semiconductor region and the active region, in which a deepest position P1 of the second region is positioned between a first well layer of the superlattice region and a first well layer of the light emitting region.

A shallowest position P2 of the first region may be positioned between the first well layer and a last well layer of the light emitting region.

The superlattice region further includes a first superlattice, a second superlattice, and an intermediate layer disposed between the first superlattice and the second superlattice, and a lowest position of In in the intermediate layer may be deeper than the deepest position P1 of the second region.

An absolute value of the slope of the second dopant profile in the first region may be greater than that of a slope of an Al profile.

An absolute value of the slope of the second dopant profile in the second region may be greater than that of a slope of an Al profile.

A starting position of a base region of the Al profile may be deeper than that of a base region of the second dopant profile, and an absolute value of a slope of the Al profile near the starting position of the base region of the Al profile may be greater than that of a slope of the second dopant profile near the starting position of the base region of the second dopant profile.

The light emitting diode may include a plurality of approach regions, and widths or heights of the plurality of approach regions may be different from each other.

In the plurality of approach regions, positions and heights of points where the first regions and the second regions intersect may be different from one another.

A light emitting module according to an embodiment of the present disclosure includes at least two light emitting diodes described above.

Widths or heights of approach regions of the two light emitting diodes may be different from each other.

### DESCRIPTION OF DRAWINGS

FIG. 1 is a schematic cross-sectional view illustrating a nitride-based light emitting diode according to an embodiment of the present disclosure.

FIG. 2 illustrates SIMS profiles of a nitride light emitting diode according to an embodiment of the present disclosure.

FIG. 3 illustrates profiles of Mg and Si among the SIMS profiles of FIG. 2.

FIG. 4 illustrates profiles of Mg and In among the SIMS profiles of FIG. 2.

FIG. 5 illustrates profiles of Mg and Al among the SIMS profiles of FIG. 2.

FIG. 6 is a schematic plan view illustrating a light emitting module according to an embodiment of the present disclosure.

### DETAILED DESCRIPTION OF EMBODIMENTS

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, interconnection connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

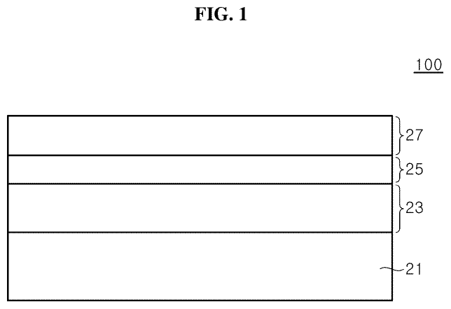

FIG. 1 is a schematic cross-sectional view illustrating a light emitting diode 100 according to an embodiment of the present disclosure.

Referring to FIG. 1, the light emitting diode 100 includes a substrate 21, a first conductivity type semiconductor region 23, a light emitting region 25, and a second conductivity type semiconductor region 27.

The substrate 21 may be a growth substrate for growing a gallium nitride semiconductor layer, for example, a sapphire substrate, a silicon substrate, a SiC substrate, a spinel substrate, a Ga₂O₃ substrate, and others. In an embodiment, the substrate 21 may be a patterned sapphire substrate. The substrate 21 may be removed from the light emitting diode 100.

The first conductivity type semiconductor region 23 is a region for injecting electrons into the light emitting region 25, and includes a first conductivity type contact layer. The first conductivity type semiconductor region 23 may have a multilayer structure, and for example, may include a buffer layer, an undoped layer, a first conductivity type contact layer, a superlattice layer, and the like.

The light emitting region 25 may have a multi quantum well structure. The light emitting region 25 may include a plurality of barrier layers and well layers, and light is generated through the combination of electrons and holes in the well layers. The well layer may include, for example, InGaN or InAlGaN, and the barrier layer may include GaN, AlGaN, or InAlGaN.

The second conductivity type semiconductor region 27 is a region for injecting holes into the light emitting region 25 and may include an electron blocking layer and a second conductivity type contact layer. For example, the electron blocking layer may include AlGaN, and the second conductivity type contact layer may include GaN or InAlGaN.

The first conductivity type semiconductor region 23 includes a first dopant for electron generation, and includes an n-type impurity such as Si. In addition, the second conductivity type semiconductor region 27 includes a second dopant to generate holes, and includes a p-type impurity such as Mg. In embodiments of the present disclosure, a second dopant profile includes an approach region AR that is at least partially overlapped with the light emitting region 25, and accordingly, a reaching distance from a region where holes exist to the light emitting region 25 may be reduced, thereby making it easy to inject holes into the light emitting region 25, and thus, improving the radiation efficiency.

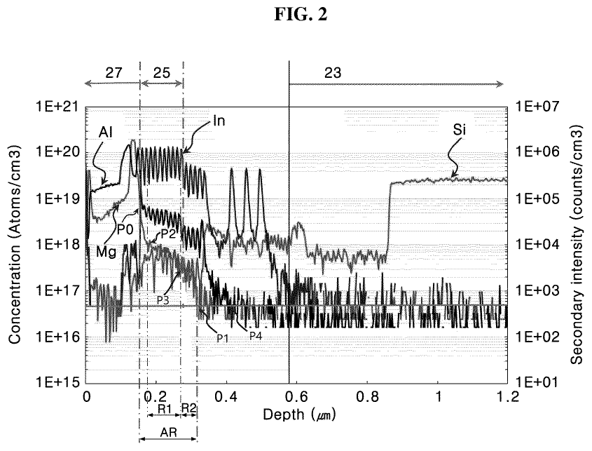

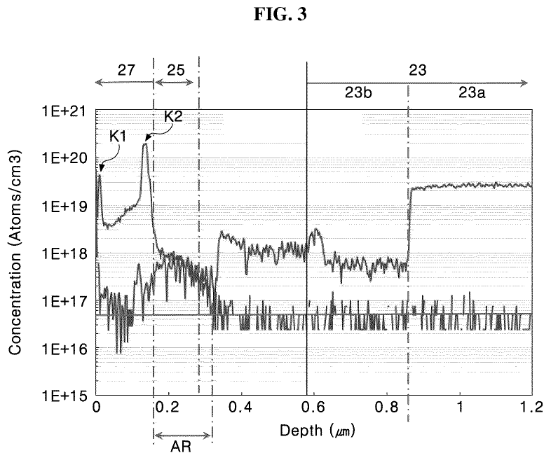

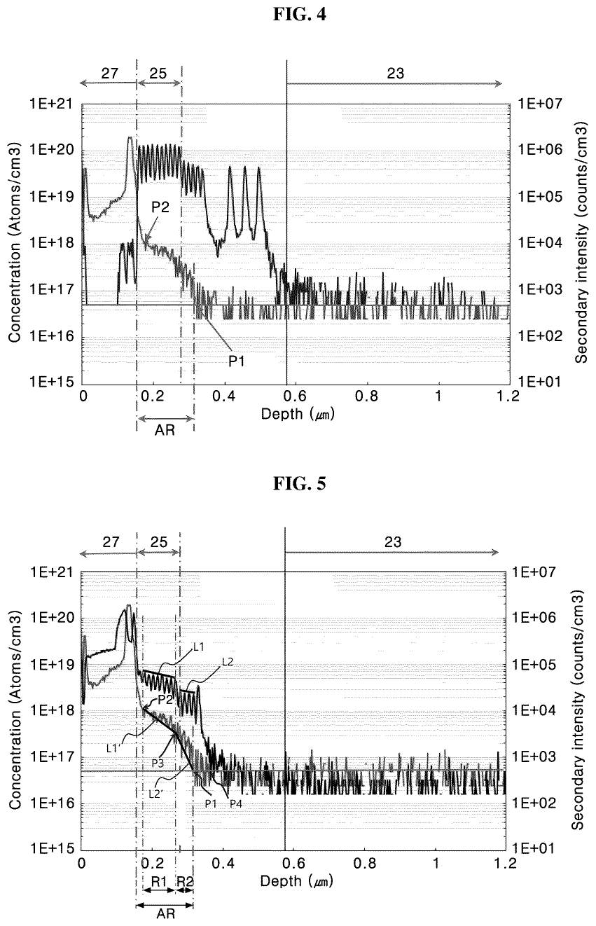

FIG. 2 illustrates profiles showing contents of materials of a nitride-based light emitting diode according to an embodiment of the present disclosure by using SIMS, FIG. 3 illustrates profiles of Mg and Si among the content profiles of FIG. 2, FIG. 4 illustrates profiles of Mg and In among the profiles of FIG. 2, and FIG. 5 illustrates profiles of Mg and Al among the profiles of FIG. 2. An x-axis of the profile represents a depth from a surface of the second conductivity type semiconductor region 27 to an interior thereof, and a y-axis represents the number of atoms per unit volume (cm³), that is, a concentration thereof. It should be noted that the y-axis is expressed on a logarithmic scale, and a slope described below refers to a slope for a logarithmic value taken from the logarithm. That is, a slope of two points (x1, y1) and (x2, y2) in the profile is expressed as (log_{y2}−log_{y1})/(x2−x1).

First, referring to FIGS. 2 and 3, the profiles represent depth profiles of Al, In, Mg, and Si from the surface of the second conductivity type semiconductor region 27. A beam size used for measurement is 90 μm×90 μm.

The first conductivity type semiconductor region 23 includes a first dopant, and the first dopant may be Si. The first conductivity type semiconductor region 23 includes a region doped with a high concentration of the first dopant and a region doped with a low concentration of the first dopant. Additionally, a single or at least two types of superlattice regions may be included between the first conductivity type semiconductor region 23 and the light emitting region 25. In a case that at least two types of superlattice regions are included, a superlattice region (a second superlattice) closer to the light emitting region 25 may be formed of thinner layers or may include more layers than a superlattice region (a first superlattice) which is farther from the light emitting region 25. Therefore, defects propagating to the light emitting region 25 may be effectively removed. The first superlattice may include, for example, InGaN/GaN, and the second superlattice may include InGaN/GaN, InAlGaN/GaN, or InAlGaN/InAlGaN.

Meanwhile, the second conductivity type semiconductor region 27 may include the electron blocking layer and the second conductivity type contact layer, and the electron blocking layer may include AlGaN or InAlGaN. The second conductivity type semiconductor region 27 may include a second dopant, and the second dopant may include Mg. The electron blocking layer may be formed as a single layer, but may also be formed as a multilayer structure with different Al compositions from one another. The second conductivity type contact layer may include a delta-doped layer heavily doped with p-type impurities.

### Second Dopant Profile

The second dopant exhibits a relatively high doping concentration on the surface within the second conductivity type semiconductor region 27, and exhibits a highest doping concentration at a position adjacent to the light emitting region 25. As illustrated in FIG. 2, the second dopant profile may have at least two peaks within a region overlapped with the second conductivity type semiconductor region 27. As can be clearly seen in FIG. 3, the at least two peaks include a first peak Kl near the surface and a second peak K2 near the light emitting region 25. As a depth increases in a region between the first peak K1 and the second peak K2, a section where the doping concentration of the second dopant increases may be formed. Therefore, a film quality in a region near an upper surface may be improved, thereby reducing a driving voltage.

Meanwhile, the second dopant profile of the light emitting diode 100 may include an approach region AR disposed between the first conductivity type semiconductor region 23 and the second conductivity type semiconductor region 27. The approach region AR may be disposed between the second peak of the second dopant and the first conductivity type semiconductor region 23. A starting point PO of the approach region AR may be a point where the second dopant profile and an indium profile intersect between an indium profile peak of the well layer of the light emitting region 25 that is disposed closest to the second conductivity type semiconductor region 27 and the second peak of the second dopant. The approach region AR may extend from the starting point toward the first conductivity type semiconductor region 23, and the concentration of the second dopant may be reduced to 5E16/cm³ or less. Therefore, a point where the concentration of the second dopant becomes 5E16/cm³ may be a first point P1 of the approach region AR. The first point P1 of the second dopant profile may be a starting point of a base region. The starting point of the base region of the second dopant profile means a region where a lowest value expressible in the second dopant profile appears, and in a case that it is difficult to clearly define the base region, an inner side from a position where the second dopant concentration first exhibits a value of 5E16/cm³ may be defined as the base region. A depth of the approach region AR formed along the x-axis may be greater than that of an active region 25. Therefore, an access distance of the second dopant to the active region 25 may be shortened, thereby increasing the radiation efficiency.

The approach region AR may include a first region R1 extending from a third point P3 that is a same depth as the indium peak of the first well layer of the light emitting region 23 in a direction toward the second conductivity type semiconductor region 27 to a second point P2 where the second dopant concentration becomes 1E18/cm3. The first region R1 continues from the second peak and the second dopant concentration may be decreased gradually as the depth increases. In addition, the approach region AR may include a second region R2 that extends from the first region R1 to the first conductivity type semiconductor region 23 and in which the concentration of the second dopant decreases relatively sharply. The second region R2 may be disposed between the first region R1 and the first conductivity type semiconductor region 23. As the depth decreases from the first region R1, the concentration of the second dopant increases, connecting to the second peak. At least a portion of the approach region AR is overlapped with the light emitting region 25, and the first region R1 may be overlapped with the light emitting region 25. Therefore, a case of an injection amount of the second dopant varying depending on a position of the well layer in the light emitting region 25 may be prevented. Furthermore, an entire second region R2 may be overlapped with the light emitting region 25. Meanwhile, a portion of the second region R2 may be overlapped with the light emitting region 25, and remaining portions thereof may be overlapped with the superlattice region. A slope of the first region R1 is gentler than that of the second region R2. The first region R1 may be a profile having a second dopant concentration of 1E17/cm3 to 1E18/cm³. The second region R2 may be a profile having a second dopant concentration of 1E17/cm³ to 5E16/cm³. In this specification, in a case that many numbers of peaks and valleys are connected, a slope means a slope of a line connecting a first peak and a last peak or a slope of a line connecting a first valley and a last valley. In the approach region AR, a peak-to-peak slope may be gentler than a valley-to-valley slope.

Furthermore, an absolute value of the slope of the first region RImay be smaller than that of a slope of a section in which the concentration of the second dopant increases in the region between the first peak and the second peak within the second conductivity type semiconductor region 27. An absolute value of the slope of the second region R2 may be greater than that of the slope of the section in which the concentration of the second dopant increases in the region between the first peak and the second peak within the second conductivity type semiconductor region 27. Therefore, it is possible to prevent the second dopant from diffusing into the first conductivity type semiconductor region 23. In addition, an absolute value of an overall slope of the approach region AR may be greater than that of the slope of the section in which the concentration of the second dopant increases in the region between the first peak and the second peak within the second conductivity type semiconductor region 27. The slope of the first region R1 has a negative value, and the slope of the section in which the concentration of the second dopant increases in the region between the first peak and the second peak has a positive value. The slope may be a rate of change in concentration with thickness in a corresponding section.

### Comparison of Second Dopant Profile and First Dopant Profile

As illustrated in FIG. 3, the first conductivity type semiconductor region 23 includes

a high concentration doping region 23a and a low concentration doping region 23b. Herein, a high concentration and a low concentration are used to relatively represent the high concentration doping region 23a and the low concentration doping region 23b, and the high concentration doping region 23a has a first dopant concentration relatively higher than that of the low concentration doping region 23b. The first dopant doping concentration of the high concentration doping region 23a may be lower than that of the first peak or the second peak of the second dopant profile within the second conductivity type semiconductor region 27, and may be higher than that of a region of increased doping concentration of the first dopant between the first peak and the second peak.

Meanwhile, a maximum doping concentration of the first dopant within the low concentration doping region 23b may be higher than an average concentration of the second dopant in the approach region AR. Herein, the average concentration can be seen as a sum of a highest value and a lowest value in a corresponding region divided by 2. In an embodiment, a highest doping concentration of the first dopant within the low concentration doping region 23b may be higher than a highest doping concentration of the second dopant in the approach region AR. Therefore, the radiation efficiency may be increased by balancing speeds of the first dopant and the second dopant entering the light emitting region 25.

Meanwhile, a concentration profile of the first dopant in the approach region AR of the second dopant may have a slope different from that of the approach region AR of the second dopant. For example, a slope of a concentration profile of the second dopant in the first region R1 may be different from that of a concentration profile of the first dopant, and a slope of a concentration profile of the second dopant in the second region R2 may be different from that of a concentration profile of the first dopant. The concentration profile of the first dopant in the approach region AR of the second dopant may intersect the concentration profile of the approach region AR of the second dopant. As illustrated in FIG. 3, a doping concentration profile of the second dopant in the first region R1 may be steeper than that of the first dopant, and a doping concentration profile of the second dopant in the second region R2 may be gentler than that of the first dopant. The average concentration of the second dopant in the approach region AR may be higher than that of the first dopant in the approach region AR. Herein, the average concentration can be seen as a sum of a highest value and a lowest value in a corresponding region divided by 2. A difference between a highest concentration and a lowest concentration of the second dopant in the approach region AR may be greater than a difference between a highest concentration and a lowest concentration of the first dopant in the approach region AR. Therefore, a diffusion speed of the second dopant may be increased by increasing the concentration difference of the second dopant.

### Comparison of Second Dopant profile and In Profile

As illustrated in FIG. 4, an In profile shows the light emitting region 25 and the superlattice region. In addition, an InGaN or InAlGaN layer may be disposed on or around the electron blocking layer within the second conductivity type semiconductor region 27. Accordingly, the In profile may be included within the second conductivity type semiconductor region 27.

Meanwhile, the first point P1 of the approach region AR may be disposed outside the light emitting region 25. Furthermore, the first point P1 of the approach region AR may be positioned between the first conductivity type semiconductor region 23 and the first well layer of the light emitting region 25. The starting point PO of the approach region AR may be the point where the second dopant profile and the indium profile intersect between the indium profile peak of the well layer of the light emitting region 25 that is disposed closest to the second conductivity type semiconductor region 27 and the second peak of the second dopant. Meanwhile, the second point P2 of the first region R1 of the approach region AR may be positioned between the first well layer and a last well layer of the light emitting region 25. Furthermore, the second point P2 may be disposed closer to the second conductivity type semiconductor region 27 with respect to a center of the light emitting region 25. Therefore, it is possible to prevent the second dopant from moving into the first conductivity type semiconductor region 23.

In another embodiment, the superlattice region may include a first superlattice region and a second superlattice region, and an intermediate layer is disposed between the first and second superlattice regions, in which a lowest In concentration of the intermediate layer is lower than a lowest In concentration of the first superlattice and the second superlattice. The lowest In concentration of the intermediate layer may be positioned closer to the second conductivity type semiconductor region 23 than the position P1, without being limited thereto, and may be positioned between the first point P1 and the second point P2.

### Comparison of Second Dopant Profile and Al Profile

As illustrated in FIG. 5, the profile of the second dopant within the approach region AR includes a first region R1 disposed relatively closer to the second conductivity type semiconductor region 27 and a second region R2 disposed relatively closer to the first conductivity type semiconductor region 23, and a profile of Al similar to this, also includes regions having different slopes within the approach region.

In the first region R1, a slope of the second dopant profile for example, a slope of an extension line L1′ connecting the second point P2 and the third point P3, is steeper than a slope of a first extension line L1 connecting a first Al peak and a last Al peak of the Al profile, and in the second region R2, a slope of the profile of the second dopant, for example, a slope of an extension line L2′ connecting the third point P3 and the first point P1, is steeper than a slope of a second extension line L2 extending the first Al peak and the last Al peak of the Al profile. Therefore, the second dopant may diffuse beyond the Al peaks due to a difference in a second dopant content in layers containing Al. Meanwhile, a fourth point P4 where the Al profile intersects a point of 5E16/cm³ may be deeper than the first point P1 where the second dopant concentration of the second dopant profile becomes 5E16/cm³. That is, the fourth point P4 of Al profile is disposed closer to the first conductivity type semiconductor region 23 than the first point P1 of the second dopant profile. In other words, the first point P1 of the second dopant profile is disposed closer to the second conductivity type semiconductor region 27 than the fourth point P4 of the Al profile. Therefore, it is possible to prevent the second dopant from diffusing into the first conductivity type semiconductor region 23.

According to embodiments of the present disclosure, the radiation efficiency may be improved by disposing the approach region AR at a depth overlapped with the active region 25.

A light emitting diode according to another embodiment of the present disclosure may include a plurality of approach regions, and the plurality of approach regions may have different shapes from one another. For example, the points P0, P1, P2, P3, and P4 described above may appear at different depths, and widths and heights of the approach regions may be different from one another. Alternatively, widths and heights of first regions and second regions of the approach regions may be different from one another. Accordingly, depths and/or concentrations at positions where the first and second regions meet may be different from one another.

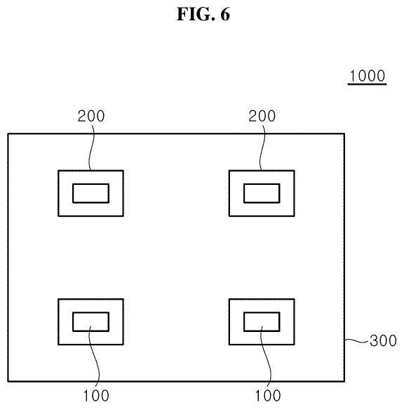

FIG. 6 is a schematic plan view illustrating a light emitting module according to an embodiment of the present disclosure.

Referring to FIG. 6, a light emitting module 1000 according to the present embodiment may include a plurality of packages 200 disposed on a circuit board 300, and each package 200 may include the light emitting diode 100 described above.

The number of packages disposed on the circuit board 300 is not particularly limited. A shape of the package 200 is not particularly limited, and may include a chip scale package. The light emitting diode 100 may be driven by being electrically connected to the circuit board 300.

In this embodiment, light emitting diodes in the packages 200 disposed at different positions have similar layer structures, and emit lights having a peak wavelength deviation of within 10 nm. However, content profiles of materials for at least two different light emitting diodes 100 are different from one another. For example, the positions P1 and P2 described above may appear at different depths, or widths and heights of approach regions AR included by each of at least two different light emitting diodes 100 may be different from each other.

While specific embodiments and aspects of the present disclosure have been illustrated and described, various changes and modifications may be made without departing from the spirit and scope of the present disclosure. Moreover, although various aspects are described herein, these aspects need not be used in combination. Accordingly, the following claims are intended to cover all changes and modifications within the scope shown and described herein.

1. A light emitting diode, comprising, a first conductivity type semiconductor region comprising a first dopant;
a light emitting region including a barrier layer and a well layer;
a second conductivity type semiconductor region comprising a second dopant; and
an approach region disposed between the first conductivity type semiconductor region and the second conductivity type semiconductor region, wherein:
a profile of the second dopant extends from the second conductivity type semiconductor region to the approach region, and
at least a portion of the approach region is overlapped with the light emitting region.

2. The light emitting diode of claim 1, wherein the approach region comprises a first region having a first slope and a second region having a second slope steeper than the first slope of the first region.

3. The light emitting diode of claim 2, wherein an absolute value of a peak-to-peak slope in the first region is smaller than an absolute value of a peak-to-peak slope in the second region.

4. The light emitting diode of claim 2, wherein an absolute value of a valley-to-valley slope in the first region is smaller than an absolute value of a valley-to-valley slope in the second region.

5. The light emitting diode of claim 1, wherein the profile of the second dopant has a peak near a surface of the second conductivity type semiconductor region and a peak near the light emitting region within the second conductivity type semiconductor region, and the profile of the second dopant has a region in which a concentration of the second dopant increases as a depth increases between the peaks.

6. The light emitting diode of claim 5, wherein the approach region comprises a first region having a first slope and a second region having a second slope steeper than the first slope of the first region, and an absolute value of a slope of the region in which the concentration of the second dopant increases between the peaks is greater than an absolute value of the slope of the first region.

7. The light emitting diode of claim 2, wherein a slope of the profile of the second dopant in the first region is different from a slope of the profile of the first dopant.

8. The light emitting diode of claim 2, wherein a slope of the profile of the second dopant in the second region is different from a slope of the profile of the first dopant.

9. The light emitting diode of claim 1, wherein the first conductivity type semiconductor region comprises a high concentration doping region doped with a relatively high concentration of the first dopant and a low concentration doping region doped with a relatively low concentration of the first dopant, and a concentration of the first dopant in the high concentration doping region is higher than a concentration of a second dopant in the approach region.

10. The light emitting diode of claim 9, wherein the approach region comprises a first region having a first slope and a second region having a second slope steeper than the first slope of the first region, and a maximum concentration of a profile of the first dopant in the low concentration doping region is higher than maximum concentrations of second dopants in the first region and the second region.

11. The light emitting diode of claim 2, further comprising a superlattice region disposed between the first conductivity type semiconductor region and an active region, wherein a deepest position of the second region is positioned between a first well layer of the superlattice region and a first well layer of the light emitting region.

12. The light emitting diode of claim 11, wherein a shallowest position of the first region is positioned between the first well layer and a last well layer of the light emitting region, the first well layer and the last well layer forming boundaries of the light emitting region.

13. The light emitting diode of claim 11, wherein the superlattice region further comprises a first superlattice, a second superlattice, and an intermediate layer disposed between the first superlattice and the second superlattice, and a lowest position of an Indium (In) profile of the intermediate layer is deeper than the deepest position of the second region.

14. The light emitting diode of claim 2, wherein an absolute value of a slope of the profile of the second dopant in the first region is greater than an absolute value of a slope of an Aluminum (Al) profile.

15. The light emitting diode of claim 2, wherein an absolute value of a slope of the profile of the second dopant in the second region is greater than an absolute value of a slope of an Aluminum (Al) profile.

16. The light emitting diode of claim 2, wherein a base region starting position of an Aluminum (Al) profile is deeper than a base region starting position of the profile of the second dopant, and an absolute value of a slope of the Al profile near the base region starting position of the Al profile is greater than an absolute value of a slope of the profile of the second dopant near the base region starting position of the profile of the second dopant.

17. The light emitting diode of claim 2, comprising a plurality of approach regions having different widths or heights from one another.

18. The light emitting diode of claim 17, wherein in the plurality of approach regions, positions and heights of points where first regions and second regions intersect are different from one another.

19. A light emitting module, comprising at least two light emitting diodes, wherein each light emitting diode includes:
a first conductivity type semiconductor region comprising a first dopant;
a light emitting region including a barrier layer and a well layer;
a second conductivity type semiconductor region comprising a second dopant; and
an approach region disposed between the first conductivity type semiconductor region and the second conductivity type semiconductor region, wherein:
a profile of the second dopant extends from the second conductivity type semiconductor region to the approach region, and
at least a portion of the approach region is overlapped with the light emitting region.

20. The light emitting module of claim 19, wherein widths or heights of approach regions of the at least two light emitting diodes are different from each other.
